(19) United States
(12) Patent Application Publication
(10) Pub. No.: US 2009/0026567 A1
(43) Pub. Date: Jan. 29, 2009

(54) Image sensor package structure and method for fabricating the same

(75) Inventors: Shou-Lung Chen, Yangmei Township (TW); Li-Cheng Shen, Hsinchu City (TW)

Correspondence Address: BACON & THOMAS, PLLC, 625 SLATERS LANE, FOURTH FLOOR, ALEXANDRIA, VA, 22314-1176, US

(73) Assignee: INDUSTRIAL TECHNOLOGY RESEARCH INSTITUTE, Hsinchu (TW)

(21) Appl. No.: 12/149,111

(22) Filed: Apr. 28, 2008

Related U.S. Application Data
(63) Continuation-in-part of application No. 11/188,529, filed on Jul. 26, 2005, now abandoned.

(30) Foreign Application Priority Data
Jul. 28, 2004 (TW) 093122552

(51) Int. Cl. H01L 21/50; H01L 31/02

(52) U.S. Cl. 257/434; 438/26; 257/E21.499; 257/E31.11

(57) ABSTRACT

A method for fabricating an image sensor package is disclosed, comprising: providing a wafer having a plurality of image sensor integrated circuits, each of which has a photosensitive active region and at least one first bonding pad; joining a transparent protecting material to the wafer wherein the photosensitive active region of the image sensor integrated circuit is covered by the transparent protecting material; forming a plurality of through holes in the transparent protecting material, the through holes being correspondingly to the first bonding pad of the wafer to expose the first bonding pad; and dicing the wafer to form a plurality of image sensor integrated circuit components. The method for fabricating an image sensor package of the present invention decreases the defects of the photosensitive active region and reduces the size of the package structure.

This application is a continuation-in-part application of pending U.S. application Ser. No. 11/188,529 filed Jul. 26, 2005.

### BACKGROUND OF THE INVENTION

1. Field of the Invention

The present invention relates to a semiconductor integrated circuit package structure and method for fabricating the same, and more particularly, to an image sensor package structure and method for fabricating the same.

2. Description of Related Art

“Multilayered package” is one of the most advanced processes for fabricating semiconductor integrated circuit (IC) products. It can increase the distance between electrodes of an IC die having multilayered package electric circuits, protect the IC die from the internal and external stresses of the package, establish an adequate thermal path for dissipating heat generated by the IC die, and provide an electrical interconnection. The packaging method for the IC dies relates closely to the packaging system used and it dominates the total cost, performance and reliability of the whole package IC die.

Conventional image sensors generally adopt a leadless chip carrier (LCC) package, such as a charge coupled device (CCD) image sensors or complementary metal oxide semiconductor (CMOS) image sensors.

The CCD image sensor is an electronic device capable of converting an optical pattern or image into a charged pattern or an electronic image. The CCD image sensor comprises a number of photosensitive units capable of modifying, storing and transferring a charge to other photosensitive units. The photosensitivity of silicon selected will affect the design of the CCD image sensor. Each photosensitive unit represents a pixel. And the array structure and matrix structure of the pixels are dominated by the semiconductor technology and its design rule. The output signal of the CCD image sensor is modified by one or more amplifiers disposed on the edge of the die. An electronic image is obtained by a series of pulses sequentially outputted to an output amplifier, each pulses output the charge of one pixel to the output amplifier in order of array. Then, the output amplifier converts the charge into a corresponding voltage. An external electric circuit transfers the output voltage signal to other components in an appropriate form for further detecting or picking-up.

The CMOS image sensors can operate at a voltage lower than the operative voltage of the CCD image sensors. Thus, the CMOS image sensor can reduce power consumption and facilitate the portability thereof. Because each CMOS active-pixel sensing unit has its own amplifier for buffering, each pixel sensing unit is capable for reading/writing independently. A conventional pixel sensing unit has four transistors and a photosensitive unit. The pixel sensing unit comprises: a transfer gate for separating the photosensitive unit from a floating diffusion having a capacitance, a reset gate interposed between the floating diffusion and a power supply, a source-follower transistor for temporarily storing the capacitance of the read-out line in the floating diffusion, and a row of select gates connecting the pixel sensing unit to the read-out line. All the pixel sensing units connected in column are connected to a shared sense amplifier.

Due to the decoupling and crystallization features of the CMOS image sensors, the CMOS image sensors have lowered power consumption and simple schemes than the CCD image sensors. Hence, a miniature CMOS image sensor is easy to design, and fewer supporting circuits thereof are required.

FIG. 6 shows a traditional leadless chip carrier package 30 generally used for the CCD or CMOS image sensor IC dies. The leadless chip carrier package 30 comprises a transparent cap layer 32 of glass having a supporting layer 35. An anti-reflection coating 34 is interposed between the glass cap 32 and the supporting layer 35. A multilayered substrate 36 having a castle-shaped structure 42 and an image sensor chip 38 thereon is provided. An upper lead 40 extending from the chip 38 is electrically connected with a lower lead 44 encasing the bottom and the sides of the substrate 36. The transparent glass cap 32 facilitates the light transmission to the image sensor chip 38.

The leadless chip carrier package 30 generally has a minimum thickness 46 of about 2 mm. Therefore, when an image sensor is packaged with the leadless chip carrier package 30, a relatively large space is required. And in most cases, this over-sized image sensor limits the utilization of the leadless chip carrier package 30.

In addition, during the traditional image sensor package processes including adhering, wire bonding and sealing of the image sensor die, the photosensitive unit of the image sensor die is usually exposed. In other words, the glass cap covering the photosensitive unit of the image sensor die is generally formed after the wafer having image sensor integrated circuits is diced into small components, in the traditional package process. Moreover, there is generally a cavity formed between the glass cap and the photosensitive unit. As a result, particles will fall onto the surface of the photosensitive unit during the package processes, causing undesirable defects of the image sensor die that decreases the yield of the packaging processes. It is therefore desirable to provide an improved package structure and method for fabricating the same to avoid defects of the photosensitive unit and to reduce the size of the resulting package structure.

### SUMMARY OF THE INVENTION

A primary object of the present invention is to provide a method for fabricating an image sensor package to prevent particles from falling onto the surface of the image sensor, avoid defects of the image sensor and increase the package yield.

Another object of the present invention is to provide an image sensor package structure to reduce the size of the package structure, especially the package thickness, make the package structure easy to modularize and prevent particles from falling onto the surface of the image sensor.

To attain the aforesaid object, a method for fabricating an image sensor package of the present invention comprises: providing a wafer having a plurality of image sensor integrated circuits, wherein each of the image sensor integrated circuits having a photosensitive active region and at least one first bonding pad; joining a transparent protecting material to the wafer, wherein the photosensitive active region of the image sensor integrated circuit is covered by the transparent protecting material; forming a plurality of through holes in the transparent protecting material, wherein the through hole are corresponding to the first bonding pad of the wafer to expose the first bonding pad; and dicing the wafer to form a plurality of image sensor integrated circuit components.

To attain the aforesaid object, an image sensor package structure of the present invention, comprises: an image sensor integrated circuit die having a first surface, wherein a photosensitive active region and at least one first bonding pad are formed on the first surface; a transparent protecting material having a plurality of through holes, wherein the transparent protecting material joins and covers the first surface of the image sensor integrated circuit die, the through hole is corresponding to the first bonding pad; a substrate having at least one second bonding pad, wherein the substrate fixedly carries the image sensor integrated circuit die; and an electrical contact connecting with the first bonding pad of the image sensor integrated circuit die and the second bonding pad of the substrate.

In the method for fabricating an image sensor package of the present invention, when the transparent protecting material is a solid state plate, preferably a glass plate, the transparent protecting material is adhered to the wafer preferably by an optical glue whose transmittance being preferably greater than 90%, or more preferably greater than 95%. Other materials having a certain transmittance can also be used for the transparent protecting material which may be in a liquid state. The liquid state transparent protecting material may be covered the wafer by printing, spin coating or the like and then be solidified. In some special cases, the optical glue is not expected to cover the sensing region in a chip to reduce the functionality of the micro-lens on the sensing pixels. However, it is also easy to coat the optical glue to dodge the sensing region. Besides, after joining the transparent protecting material to the wafer, the transparent protecting material can cover any portion of the wafer, preferably the transparent protecting material covers the wafer partially or totally. The method for forming the through holes is not specifically defined, preferably by wet etching, dry etching or laser drilling, while the laser drilling is more cost-effective. The position of the first bonding pad on the image sensor integrated circuit is not specifically defined. Preferably, the first bonding pad is disposed at the outer periphery of the photosensitive active region of an image sensor. In addition, after the formation of the through holes, a conductive material can be filled into the through holes by electroplating, electroless plating, or the combination thereof. Further, after the conductive material is filled into the through holes, a plurality of solder balls or needle-shaped pins are soldered to the through holes. Then, after the wafer is diced, the resulting image sensor integrated circuit die is mounted onto the substrate having an electric circuit by the solder balls or the needle-shaped pins. But the resulting image sensor integrated circuit die can also be carried onto the substrate having an electric circuit without the solder balls or the needle-shaped pins, wherein the resulting image sensor integrated circuit die is in contact with the substrate with the surface opposite to the photosensitive active region. The electric circuit of the substrate is connected with the first bonding pads of the image sensor integrated circuit die by a subsequent wire bonding process.

In the image sensor package structure of the present invention, the image sensor integrated circuit die is fixed to the substrate by the second surface opposing the surface where the photosensitive active region is mounted. Alternatively, the image sensor integrated circuit die is fixed to the substrate with its first surface connecting to the window of the substrate, wherein the window is facing the photosensitive active region of the image sensor integrated circuit die. Besides, in the former case, the first bonding pad of the image sensor integrated circuit die is electrically connected with the second bonding pad of the substrate by means of the wire bonding conductive wires or soldering needle-shaped pins. In the latter case, the electrical contacts are generated by filling a conductive material into the through holes and then soldering a plurality of solder balls to the through holes or forming a conductive pattern layer on the through holes. The method for filling the conductive material into the through holes is not specifically defined, preferably by electroplating, electroless plating, or the combination thereof. A package structure of the present invention may further comprise a passivation film for protecting the electrical contacts. Preferably, the passivation film can be formed by injection molding. Alternatively, an image sensor package structure of the present invention may further comprise a lens lid having at least one lens carried onto the substrate. An image is formed on the photosensitive active region of the image sensor integrated circuit die when the light passes through the lens of the lens lid.

It is to be understood that both the foregoing general description and the following detailed description are exemplary and explanatory only and are not restrictive of the present invention, as claimed.

The accompanying drawings, which are incorporated in and constitute a part of this specification, illustrate several embodiments of the present invention and together with the description, serve to explain the principles of the present invention.

### BRIEF DESCRIPTION OF THE DRAWINGS

FIGS. 1a through 1d are flow charts illustrating a process for fabricating an image sensor integrated circuit component according to a preferred embodiment of the present invention;

FIGS. 2a through 2c are flow charts illustrating a method for fabricating an image sensor package according to a preferred embodiment of the present invention;

FIG. 3 is a schematic view of an image sensor package structure according to a preferred embodiment of the present invention;

FIGS. 4a through 4c are flow charts illustrating a process for fabricating an image sensor integrated circuit component according to another preferred embodiment of the present invention;

FIG. 5 is a schematic view of an image sensor package structure according to another preferred embodiment of the present invention;

FIG. 6 is a schematic view of a traditional image sensor package structure.

### DETAILED DESCRIPTION OF THE PREFERRED EMBODIMENT

The present invention provides a photosensitivity resin compositions comprising: (A) 100 parts by weight of an alkali-soluble acrylic resin with a weight average molecule weight of 2000-300000; (B) 5 to 100 parts by weight of a compound containing a quinonediazide group; and (C) 100 to 2000 parts by weight of a solvent.

Reference will now be made in detail to present embodiments of the present invention, examples of which are illustrated in the accompanying drawings. Wherever possible, the same reference numbers will be used throughout the drawings to refer to the same or like parts.

Two preferred embodiments of the present invention will now be described to illustrate the technical contents involved in the present invention.

### Embodiment 1

### Method for Fabricating an Image Sensor Package

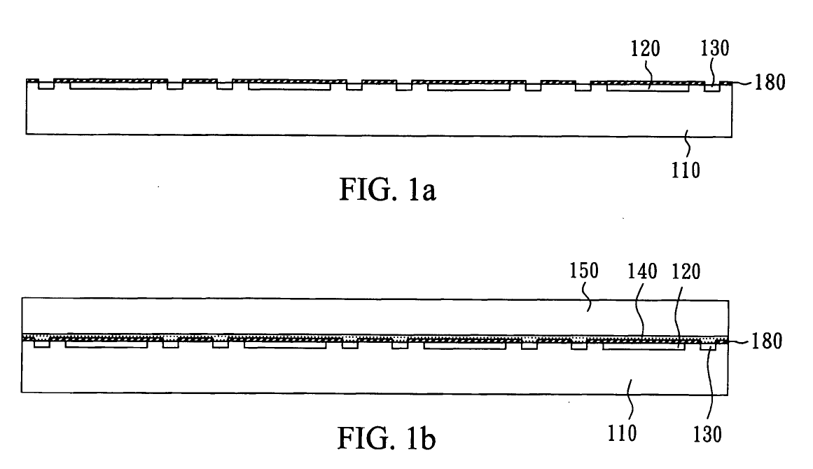

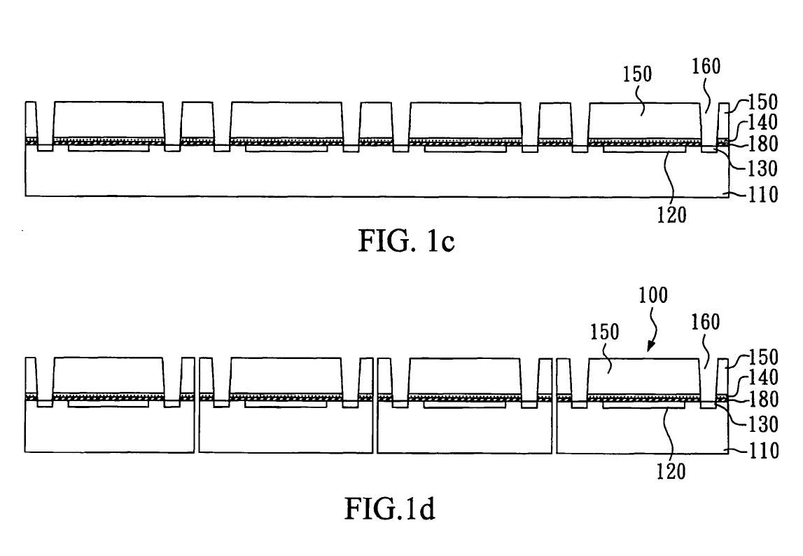

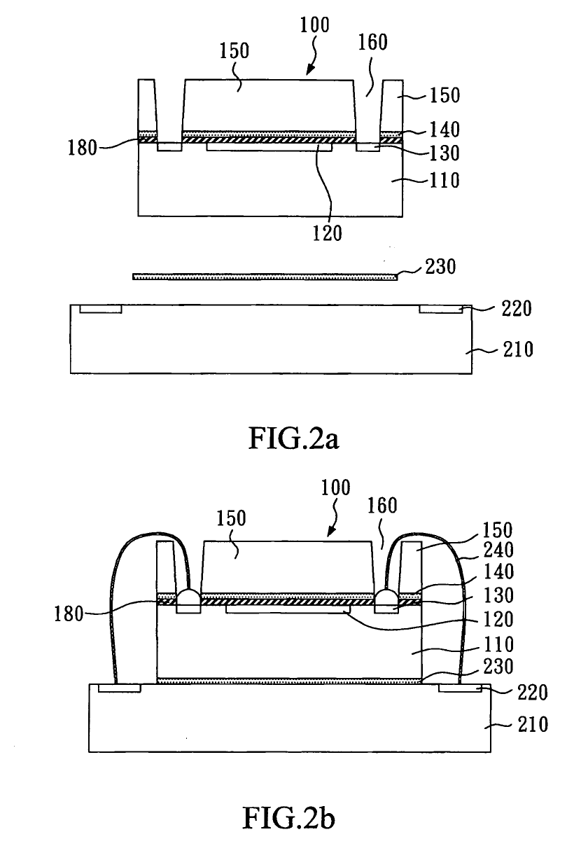

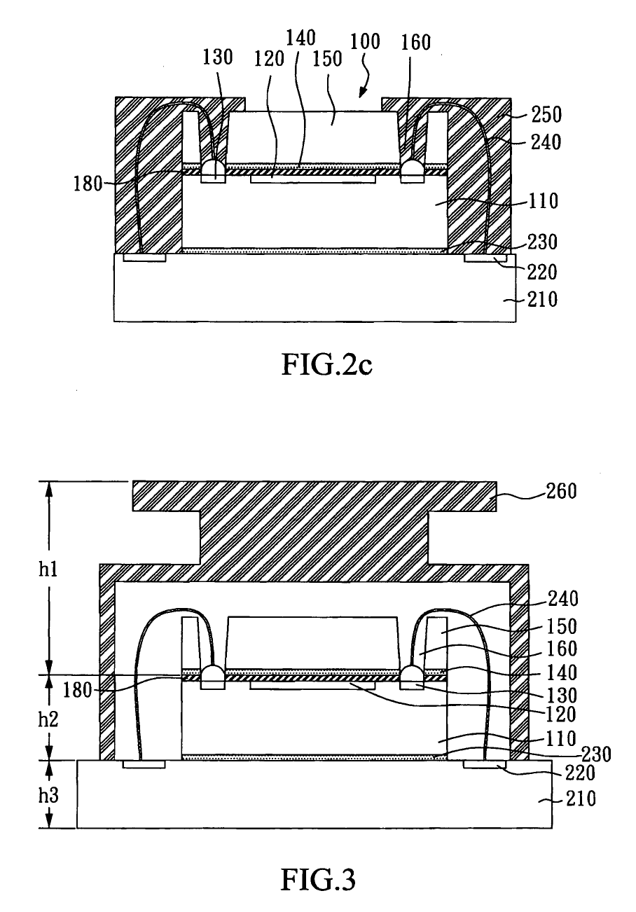

Referring to FIGS. 1a through 1d, which illustrate a method for fabricating an image sensor package of the present embodiment. As shown in FIG. 1a, a wafer 110 having a plurality of image sensor integrated circuits, each of which has a photosensitive active region 120 and a plurality of first bonding pads 130 is provided. Besides, a passivation layer 180 is formed on the surface of the wafer 110. An optical glue 140 is used to have a glass plate 150 adhesively joined to the wafer 110 by partial or whole area so that the photosensitive active region 120 of the image sensor integrated circuit is covered by the glass plate 150, as shown in FIG. 1b. The glass plate 150 can be pre-coated with an anti-reflection layer or any other layer if necessary. As shown in FIG. 1c, a plurality of through holes 160 are formed in the glass plate 150 correspondingly with the first bonding pads 130 of the wafer 110 by laser drilling, so that the first bonding pads 130 can be exposed. Then, the wafer 110 is diced to form a plurality of image sensor integrated circuit components 100, as shown in FIG. 1d. The image sensor integrated circuit component 100 is then carried onto a printed circuit board (PCB) 210, as shown in FIG. 2a. The image sensor integrated circuit component 100 is fixed onto the printed circuit board 210 having a plurality of second bonding pads 220 with an adhesive 230 thereinbetween. The surface of the image sensor integrated circuit component 100 being in contact with the printed circuit board 220 is the surface opposing the surface on which the photosensitive active region 120 and the first bonding pads 130 are disposed. Then, as shown in FIG. 2b, connection between the second bonding pads 220 of the printed circuit board 210 and the first bonding pads 130 of the image sensor integrated circuit component 100 is effected by means of conductive wires 240 formed by wire bonding. Finally, a plastic mold 250 for protecting the conductive wires 240 is formed by injection molding, as shown in FIG. 2c. On the other hand, as shown in FIG. 3, a lens lid 260 having at least one lens can be carried onto the printed circuit board 210 to protect the conductive wires 240, without the use of the plastic mold 250 in FIG. 2c. Thus, an image is formed on the photosensitive active region 120 of the image sensor integrated circuit component 100 when light passes though the lens. Besides, the space enclosed by the lens lid 260 and the printed circuit board 210 is sufficient for accommodating the whole image sensor integrated circuit component 100 and protecting the conductive wires 240 from the exterior environment.

In the present embodiment, because the image sensor integrated circuits are adhered to the glass plate prior to the dicing process of the wafer 110, the glass plate 150 is capable of protecting the photosensitive active region 120 of the image sensor integrated circuit 110. As a result, in the subsequent processing steps, such as dicing of the wafer, fixing of the image sensor integrated circuits and subsequent wire bonding and sealing, the photosensitive active region of the image sensor integrated circuit can be free form the inadvertently falling particles. And the number of the undesirable defects of the image sensor integrated circuit can be minimized and the package yield can thus be increased. Moreover, the processing steps adopted by the present invention are all known technologies so that the cost of research and development can be saved. Besides, due to the image sensor package structure of the present invention is the chip scale package (CSP), it is easy to modularized the image sensor package structure of the present invention with a compact size.

### Embodiment 2

### Method for Fabricating an Image Sensor Package

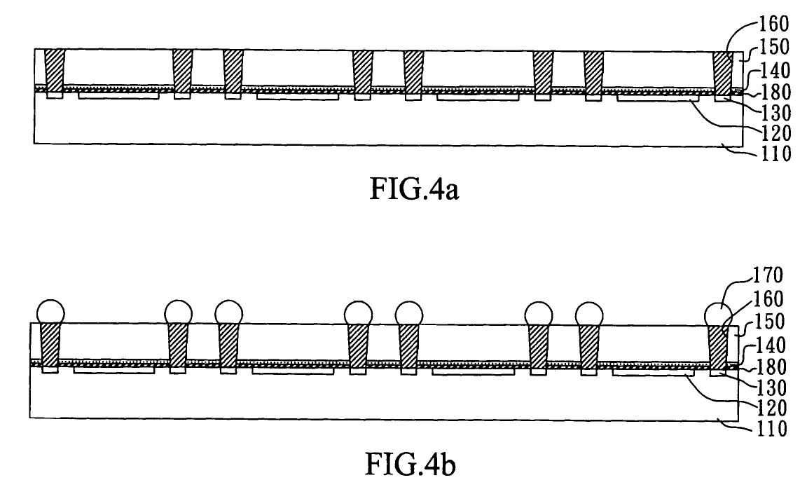

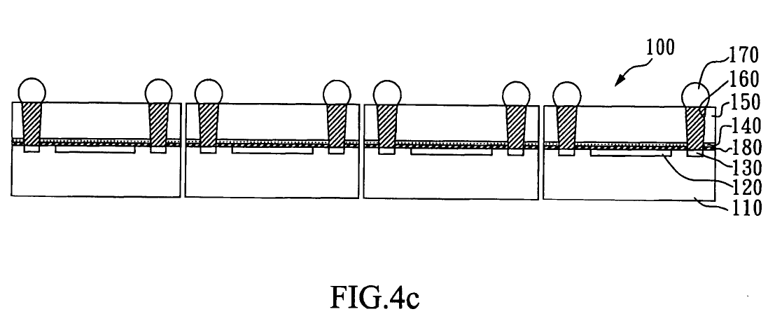

A method for fabricating an image sensor package is disclosed. First, as shown in FIG. 1a, a wafer 110 having a plurality of image sensor integrated circuits, each of which has a photosensitive active region 120 and a plurality of first bonding pads 130, is provided. Besides, a passivation layer 180 is formed on the surface of the wafer 110. As shown in FIG. 1b, an optical glue 140 is used to have a glass plate 150 adhesively joined to the wafer 110 so that the photosensitive active region 120 of the image sensor integrated circuit is covered by the glass plate 150. The glass plate 150 can be pre-coated with an anti-reflection layer or any other layer if necessary. As shown in FIG. 1c, a plurality of through holes 160 are formed in the glass plate 150, correspondingly with the first bonding pads 130 of the wafer 110 by laser drilling, so that the first bonding pads 130 can be exposed. Referring now to FIG. 4a, a conductive material is then filled into the through holes 160 by electroplating. Then, as shown in FIG. 4b, a plurality of solder balls 170 are soldered to the through holes 160. Further, the wafer 110 is diced to form a plurality of image sensor integrated circuit components 100 as shown in FIG. 4c.

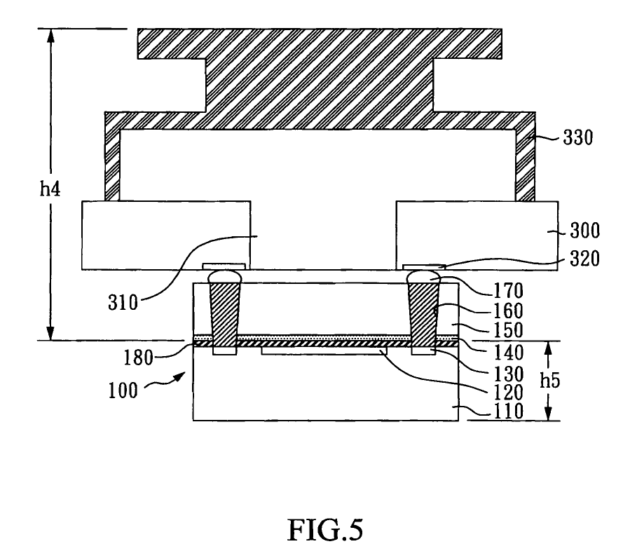

Referring now to FIG. 5, a substrate 300 having a window 310 and a plurality of second bonding pads 320 is provided. The image sensor integrated circuit component 100 of the present invention is then fixedly carried onto the substrate 300, wherein the window 310 is opposing the photosensitive active region 120 of the image sensor integrated circuit component 100 and the solder balls 170 thereof are joined to the second bonding pads 320 of the substrate 300. Finally, a lens lid 330 having at least one lens is carried onto the surface of the substrate 300, wherein the surface is opposite to the image sensor integrated circuit component 100. Thus, an image is formed on the photosensitive active region 120 of the image sensor integrated circuit component 100 when light passes through the lens.

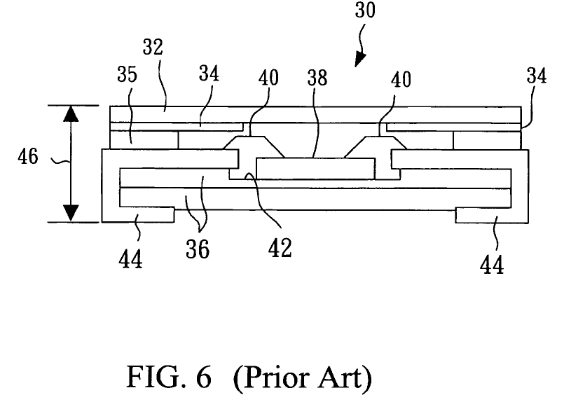

The whole package thickness of the present embodiment is the sum of the thickness (h4) measured from the lens to the photosensitive active region 120 of the image sensor integrated circuit component 100 and the thickness (h5) of the image sensor die. As shown in FIG. 3, the whole package thickness is the sum of the thickness (h1) measured from the lens to the photosensitive active region 120 of the image sensor integrated circuit component 100, the thickness (h2) of the image sensor die and the thickness (h3) of the substrate 210. On the other hand, as shown in FIG. 6, the whole package thickness of the traditional package, which is about the sum of the thickness measured from the lens to the photosensitive active region of the image sensor chip 38, the thickness of the image sensor chip 38 and the thickness of the multi-layer substrate 36, as. As a result, the whole package thickness of the present embodiment is minimum and it can minimize the whole package thickness.

Consequently, the resulting package structure of the present embodiment not only has the minimum package thickness as a whole, but also is capable of protecting the photosensitive active region of the image sensor integrated circuit in the subsequent processing steps by the glass plate covered thereon. As in the subsequent processing steps, such as dicing of the wafer, fixing of the image sensor integrated circuits and subsequent wire bonding and sealing, the photosensitive active region of the image sensor integrated circuit can be free form the inadvertently falling particles. And the number of the undesirable defects of the image sensor integrated circuit can be minimized and the package yield can thus be increased. Moreover, the processing steps adopted by the present invention are all known technologies so that the cost of research and development can be saved. Besides, due to the image sensor package structure of the present invention is the chip scale package (CSP), it is easy to modularized the image sensor package structure of the present invention with a compact size.

Other embodiments of the present invention will be apparent to those skilled in the art from consideration of the specification and practice of the present invention disclosed herein. It is intended that the specification and examples be considered as exemplary only, with a true scope and spirit of the present invention being indicated by the following claims.

What is claimed is:

1. A method for fabricating an image sensor package, comprising:
providing a wafer having a plurality of image sensor integrated circuits, wherein each of said image sensor integrated circuits having a photosensitive active region and at least one first bonding pad;
joining a transparent protecting material to said wafer, wherein said photosensitive active region of said image sensor integrated circuit is covered by said transparent protecting material;
forming a plurality of through holes in said transparent protecting material, wherein said through holes are corresponding to said first bonding pad of said wafer to expose said first bonding pad; and
dicing said wafer to form a plurality of image sensor integrated circuit components.

2. The method for fabricating an image sensor package of claim 1, wherein said transparent protecting material is in a solid state and then joining to said wafer with an optical glue, or said transparent protecting material is in a liquid state and formed by printing or spin coating.

3. The method for fabricating an image sensor package of claim 1, wherein said transparent protecting material is a glass.

4. The method for fabricating an image sensor package of claim 2, wherein the transmittance of said optical glue is greater than 90%.

5. The method for fabricating an image sensor package of claim 1, wherein said through holes are formed by wet etching, dry etching or laser drilling.

6. The method for fabricating an image sensor package of claim 1, further comprising filling a conductive material into said through holes by electroplating, electroless plating, or the combination thereof after the formation of said through holes.

7. The method for fabricating an image sensor package of claim 6, further comprising soldering a plurality of solder balls or needle-shaped pins to said through holes after said conductive material is filled into said through holes.

8. The method for fabricating an image sensor package of claim 1, further comprising carrying said image sensor integrated circuit component onto a substrate having at least one second bonding pad after said wafer is diced.

9. The method for fabricating an image sensor package of claim 8, further comprising connecting said second bonding pad of said substrate to said first bonding pad of said image sensor integrated circuit component by wire bonding after said image sensor integrated circuit component is carried onto said substrate.

10. The method for fabricating an image sensor package of claim 1, wherein said wafer is covered by said transparent protecting material partially or totally.

11. An image sensor package structure, comprising:
an image sensor integrated circuit die having a first surface, wherein a photosensitive active region and at least one first bonding pad are formed on said first surface;
a transparent protecting material having a plurality of through holes, wherein said transparent protecting material joins and covers said first surface of said image sensor integrated circuit die, said through hole is corresponding to said first bonding pad;
a transparent adhesive layer, wherein said transparent adhesive layer is located between said image sensor integrated circuit die and said transparent protecting material;
a substrate having at least one second bonding pad, wherein said substrate fixedly carries said image sensor integrated circuit die;
an electrical contact, wherein said electrical contact connects with said first bonding pad of said image sensor integrated circuit die and said second bonding pad of said substrate; and
a passivation layer, wherein said passivation layer has a plurality of vias and is located between said first surface of said image sensor integrated circuit die and said transparent adhesive layer, said via is corresponding to said first bonding pad;
wherein part of said electrical contact is formed in said through hole;
said transparent adhesive layer covers said photosensitive active region of said image sensor integrated circuit die.

12. The image sensor package structure of claim 11, wherein said imager sensor integrated circuit die is fixedly carried onto said substrate by joining said image sensor integrated circuit die to said substrate with a second surface opposing to said first surface.

13. The image sensor package structure of claim 12, wherein said electrical contact is a conductive wire formed by wire bonding or a needle-shaped pin formed by soldering.

14. The image sensor package structure of claim 11, wherein said imager sensor integrated circuit die is fixedly carried onto said substrate by forming a window opposing to said photosensitive active region on said substrate, and then joining said imager sensor integrated circuit die and said substrate with said first surface facing said window.

15. The image sensor package structure of claim 14, wherein said electrical contact is formed by filling a conductive material into said through holes and soldering a plurality of solder balls to said through holes.

16. The image sensor package structure of claim 14, wherein said electrical contact is formed by filling a conductive material into said through holes and forming a conductive pattern layer on said through holes.

17. The image sensor package structure of claim 11, further comprising a passivation film covering said electrical contact to protect said electrical contact.

18. The image sensor package structure of claim 17, wherein said passivation film is formed by injection molding.

19. The image sensor package structure of claim 11, further comprising a lens lid having at least one lens, said lens lid carries onto said substrate and an image is formed on said photosensitive active region of said image sensor integrated circuit die.

20. The image sensor package structure of claim 11, wherein said first surface is covered by said transparent protecting material partially or totally.

21. The image sensor package structure of claim 11, wherein said transparent protecting material is a glass plate.
